(19) United States
(12) Patent Application Publication
(10) Pub. No.: US 2026/0370226 A1
(43) Pub. Date: Nov. 19, 2026

(54) SENSOR DEVICE AND METHOD FOR CAPACITIVE TOUCH DETECTION

(71) Applicant: Valeo Schalter und Sensoren GmbH, Bietigheim-Bissingen (DE)

(72) Inventors: Benjamin Dietz, Bietigheim-Bissingen (DE); Sascha Staude, Bietigheim-Bissingen (DE); Miklos Molnar, Veszprem (HU); Mohamed Elamin, Bietigheim-Bissingen (DE)

(73) Assignee: Valeo Schalter und Sensoren GmbH, Bietigheim-Bissingen (DE)

(21) Appl. No.: 19/133,471

(22) PCT Filed: Nov. 22, 2023
(86) PCT No.: PCT/EP2023/082708

§ 371 Date: May 28, 2025

(30) Foreign Application Priority Data
Nov. 28, 2022 (DE) 10 2022 131 313.1

(51) Int. Cl. H03K 17/96; B62D 1/04; G01D 5/24

(52) U.S. Cl. CPC H03K 17/962; B62D 1/046; G01D 5/24

(57) ABSTRACT

Described is a sensor device for capacitive touch detection having a first potential connection for connection to a first reference potential and a second potential connection for connection to a second reference potential. An analog-to-digital converter and a sensor electrode are either linked to the first potential connection or switched into a high-impedance state. The sensor device includes a reference capacitor with a first connection, which is either linked to the second potential connection or to an input of the analog-to-digital converter. A resistance component of the sensor device is used to link the sensor electrode to the first connection of the reference capacitor. A matching capacitor of the sensor device is either connected to or removed from a parallel circuit with the reference capacitor.

The present invention relates to a sensor device for capacitive touch detection having at least one first potential connection for respectively connecting the sensor device to a first electrical reference potential and at least one second potential connection for respectively connecting the sensor device to a second electrical reference potential, an analog-to-digital converter and a sensor electrode, which is designed to be touched by a user and which can either be linked to the at least one first potential connection or switched into a high-impedance state by means of a first switching element of the sensor device, a reference capacitor having a first connection, which can either be linked to the at least one second potential connection or to an input of the analog-to-digital converter by means of a second switching element of the sensor device, and a resistance component which is used to link the sensor electrode to the first connection of the reference capacitor. The invention further relates to an input device for a motor vehicle for capturing a user input with such a sensor device and to a hand detection device for a motor vehicle steering wheel with such a sensor device. The invention also relates to a method for capacitive touch detection.

Document U.S. Pat. No. 9,823,798 B2 describes a capacitive sensor system containing a capacitive sensor device with a sensor electrode containing a first capacitor, a first supply voltage, and a first switch which can be operated in such a way that it couples the sensor electrode to the first supply voltage during a first mode and to an analog-to-digital converter during a second mode. A second switch can be operated in such a way that it couples a second capacitor to a second supply voltage during the first mode and to an open circuit during the second mode. A resistance element is provided and contains a first connection, which is connected between the first capacitor and the first switch, and a second connection, which is connected between the second capacitor and the second switch.

Document DE 10 2019 129 802 A1 describes a capacitive sensor device having a sensor electrode, a control and evaluation apparatus with a first connection contact and a second connection contact, a first connection line, and a second connection line. The sensor electrode has a first electrode connection and a second electrode connection, and the first electrode connection of the sensor electrode is linked to the first connection contact via the first connection line and the second electrode connection is linked to the second connection contact via the second connection line. The sensor device has a reference capacitance which is electrically linked to the first connection line, wherein the sensor electrode is electrically linked or linkable to the first connection contact via the electrical resistance, and wherein the reference capacitance is electrically linked on the one hand to the first connection line between the first connection contact and the electrical resistance and on the other hand to a reference potential.

Since the capacitance of the sensor electrode changes with respect to ground, depending on whether or not a user touches the sensor electrode, a touch-dependent voltage is established on the second capacitor and can be read out by means of the analog-to-digital converter the voltage of the second capacitor. Based on this, the touching of the sensor electrode or an approach to the sensor electrode, which also affects the capacitance, can be detected. Such sensor systems can be used, for example, to capacitively detect user inputs, in particular for applications in the interior of motor vehicles, for example when detecting the actuation of touch-sensitive operating panels or operating elements.

The accuracy of the voltage measurement is higher if the two capacitances are not too different from each other. The measurement range regarding the capacitance of the sensor electrode to be measured, in which an accurate measurement and thus reliable detection can be achieved, is therefore limited. For example, the capacitance of the sensor electrode may differ in different applications, since sensor electrodes of different sizes are used, for example. In addition, the capacitance of the sensor electrode can change depending on the ambient temperature.

It is an object of the present invention to improve the touch detection reliability when using a capacitive measurement principle for a larger measurement range and/or for different measurement ranges.

This object is achieved by the respective subject matter of the independent claims. The dependent claims relate to advantageous developments and preferred embodiments.

The invention is based on the idea of providing, in addition to the reference capacitor mentioned at the outset, a matching capacitor which can be either connected to a parallel circuit with the reference capacitor or removed from the parallel circuit.

According to one aspect of the invention, a sensor device for capacitive touch detection is specified. The sensor device has at least one first potential connection for respectively connecting the sensor device to a first electrical reference potential and at least one second potential connection for respectively connecting the sensor device to a second electrical reference potential, which is different from the first electrical reference potential. The sensor device has an analog-to-digital converter, AD converter, and a sensor electrode which is designed and in particular arranged to be touched by a user. The sensor electrode can either be linked to the at least one first potential connection or can be switched into a high-impedance state by means of a first switching element of the sensor device.

The sensor device has a reference capacitor with a first connection, which can either be linked to the at least one second potential connection or to an input of the analog-to-digital converter by means of a second switching element of the sensor device, and a resistance component which is used to link the sensor electrode to the first connection of the reference capacitor.

Said switching elements can be controlled in particular by means of at least one control unit of the sensor device. In particular, the at least one control unit may be configured to control the third switching element independently of the first and the second switching element. In contrast, the first and the second switching element can be controlled by the at least one control unit, for example, in such a way that the first connection of the reference capacitor and the detector electrode are linked simultaneously or substantially simultaneously to the at least one second potential connection or the at least one first potential. Analogously, the at least one control unit can control the first and the second switching element in such a way that the first connection of the reference capacitor and the detector electrode are linked simultaneously or substantially simultaneously to the input of the AD converter or switched into the high-impedance state.

The first electrical reference potential can correspond to a ground potential, for example, and the second electrical reference potential can correspond to a reference potential different from zero, for example, with the result that a reference voltage that is different from zero and is in particular positive is dropped between the first and the second reference potential. However, the first electrical reference potential can also be different from zero and the second electrical reference potential can correspond to the ground potential. Both the first electrical reference potential and the second electrical reference potential can also be different from zero.

Each of the at least one first potential connection is linked or linkable to the first electrical reference potential and each of the at least one second potential connection is linked or linkable to the second electrical reference potential. Linking the sensor electrode, the first connection of the reference capacitor or other connections or the like to the at least one first potential connection can therefore be understood as meaning a link to one of the at least one first potential connection. Linking the sensor electrode, the first connection of the reference capacitor or other connections or the like to the at least one second potential connection can be understood as meaning a link to one of the at least one second potential connection.

The terms link, linked or the like include a direct link as well as an indirect link as well as a switchable link and a non-switchable link. If a connection or the like can be switched or linked by means of a switching element or the like, this also includes a direct and an indirect link. In this case, a direct link can be understood as meaning the fact that, if necessary, in addition to the corresponding switching element, no further electrical or electronic components are arranged between the components to be linked, while an indirect link can be understood as meaning the fact that, if necessary, in addition to the corresponding switching element, one or more further electrical or electronic components, such as resistors, capacitors, coils and so on, are arranged between the components to be linked.

In particular, the switching elements can each assume a closed state and an open state. The electrical resistance of the respective switching element is then lower in the closed state, nominally equal to zero, for example, than in the open state, where it can be nominally infinitely large, for example. If the first switching element is in the closed state, the sensor electrode is linked, for example, to the at least one first potential connection, and, if the first switching element is in the open state, the sensor electrode is switched, for example, into the high-impedance state, or vice versa. If the second switching element is in the closed state, the first connection of the reference capacitor is linked, for example, to the at least one second potential connection, and, if the second switching element is in the open state, the first connection of the reference capacitor is linked, for example, to the input of the AD converter, or vice versa. If the third switching element is in the closed state, the matching capacitor is, for example, connected in parallel with the reference capacitor, and, if the first switching element is in the open state, the matching capacitor is, for example, removed from the parallel circuit, or vice versa.

The high-impedance state of the sensor electrode or of the first connection of the reference capacitor and possibly of further connections can be understood as a state in which no electrical charge can flow away to a relevant extent from the sensor electrode or the first connection of the reference capacitor and possibly the further connections, and, accordingly, no electrical charge can flow in to a relevant extent either. This can be done, for example, by opening the corresponding connection or by linking the corresponding connection to a sufficiently large electrical resistance. In individual cases, what is sufficient depends on the measurement accuracy to be achieved. Since a voltage is intended to be measured by means of the AD converter, a link to the input of the AD converter also corresponds in particular to switching into a high-impedance state.

The reference capacitor and the matching capacitor each have a known capacitance that is in particular independent of the touching of the sensor electrode. First, it is assumed that the matching capacitor is removed from the parallel circuit with the reference capacitor. If, during a charging phase, the sensor electrode is linked to the first electrical reference potential via the at least one first potential connection and the first connection of the reference capacitor is linked to the second electrical reference potential via the at least one second potential connection, the reference capacitor can be charged to the reference voltage, for example, and the effective capacitor formed by the sensor electrode with respect to ground can be brought to 0 volts, or vice versa, depending on the interconnection of the second connection of the reference capacitor. If, in a charge redistribution phase, the sensor electrode is then switched into the high-impedance state and the first connection of the reference capacitor is linked to the input of the AD converter, which also corresponds to a high-impedance state, the charge is distributed according to the current capacitance of the effective capacitor of the sensor electrode and the known capacitance of the reference capacitor. The voltage established accordingly across the reference capacitor, which can be read out or measured by means of the AD converter, in particular by means of an evaluation unit of the sensor device, indirectly reflects the capacitance of the effective capacitor of the sensor electrode, and thus whether the sensor electrode is or was touched or approached by the user.

This capacitive detection method is in particular the so-called capacitive voltage divider method, also called CVD method. The sensor electrode forms a capacitance to ground with the surrounding area, which is increased when the sensor electrode is approached or touched by the user. This change in capacitance is reflected in a changed equalization potential, and so the approach or touching can be detected accordingly.

If the matching capacitor is removed from the parallel circuit, it is isolated from the ground, for example, and thus switched to zero potential. This means that it has no electrical influence on the reference capacitor and is therefore virtually removed. In any case, the matching capacitor, when removed from the parallel circuit, does not affect the voltage that can be tapped off at the input of the AD converter and there is also no charge flowing from the effective capacitor of the sensor electrode to the matching capacitor during the charge redistribution phase, in particular the matching capacitor is not charged even during the charging phase.

If, on the other hand, the matching capacitor is connected to the parallel circuit with the reference capacitor, in particular during the charging phase, the charge redistribution phase and the measurement by the analog-to-digital converter, the total capacitance relevant to the voltage read out corresponds to the sum of the capacitances of the matching capacitor and of the reference capacitor. Depending on the measurement mode, the sensor device according to the invention can therefore only use the capacitance of the reference capacitor or the sum of the capacitances of the matching capacitor and of the reference capacitor. Thus, the measurement range, within which reliable detection of touching of the sensor electrode or approach to the sensor electrode, can be increased if required, for example in order to adapt it to the size and/or other physical properties of the sensor electrode. Furthermore, a change in the capacitance of the effective capacitor of the sensor electrode caused by changed ambient conditions, in particular ambient temperature and/or humidity of the environment, can also be compensated for by specifically connecting or removing the matching capacitor to or from the parallel circuit with the reference capacitor.

Furthermore, it is possible to use the sensor device according to the invention to check the plausibility of the measurements by means of two or more measurements with different states of the matching capacitor, that is to say in particular with the matching capacitor connected and with the matching capacitor removed from the parallel circuit. For example, the capacitance of the effective capacitor of the sensor electrode can be determined under the same ambient conditions with the matching capacitor connected and with the matching capacitor removed from the parallel circuit. In both cases, the same value for the capacitance of the effective capacitor of the sensor electrode should result within the scope of the measurement accuracies.

According to at least one embodiment of the sensor device, the sensor device has the at least one control unit which is configured to control the first, the second and the third switching element. For example, a control unit of the sensor device is configured to control the first, the second and the third switching element. Alternatively, a control unit of the sensor device is configured to control the first and the second switching element and a further control unit of the sensor device is configured to control the third switching element.

According to at least one embodiment, the at least one control unit is configured, during the charging phase, to link the sensor electrode to the at least one first potential connection by controlling the first switching element and to link the first connection of the reference capacitor to the at least one second potential connection by controlling the second switching element.

This can be understood as meaning in particular that the at least one control unit is configured to control the first and the second switching element, with the result that, at the beginning of the charging phase, the sensor electrode is linked to the at least one first potential connection and remains linked during the entire charging phase, and the first connection of the reference capacitor, in particular at the same time as the sensor electrode is linked to the at least one first potential connection, is linked to the at least one second potential connection and remains linked during the entire charging phase.

In a first interconnection example, the first reference potential P1 corresponds to a ground potential, i.e. 0 V, and the second reference potential P2 corresponds to a positive potential, for example 5 V. A second connection of the reference capacitor is linked in particular to the at least one first potential connection. In a second interconnection example, the second reference potential P2 corresponds to the ground potential, i.e. 0 V, and the first reference potential P1 corresponds to the positive potential, for example 5 V. The second connection of the reference capacitor is linked in particular to the at least one second potential connection. The following explanations can be transferred, however, analogously to any other examples.

In the first interconnection example, the sensor electrode is not charged or discharged with respect to ground or is charged to 0 V during the charging phase, and the reference capacitor is charged to a voltage U=P1), for example 5 V. If the matching capacitor is connected in parallel with the reference capacitor during the charging phase, it is also charged to voltage U. In the second interconnection example, the reference capacitor is not charged or discharged or is charged to 0 V during the charging phase, and the sensor electrode is charged to a voltage U′=P1 with respect to ground, for example 5 V. If the matching capacitor is connected in parallel with the reference capacitor during the charging phase, it is also discharged or charged to 0 V.

According to at least one embodiment, the at least one control unit is configured, during a charge redistribution phase following, in particular immediately following, the charging phase, to switch the sensor electrode into the high-impedance state by controlling the first switching element and to link the first connection of the reference capacitor to the input of the AD converter by controlling the second switching element.

This can be understood as meaning in particular that the at least one control unit is configured to control the first and the second switching element, with the result that, at the beginning of the charge redistribution phase, the sensor electrode is switched into the high-impedance state and remains switched during the entire charge redistribution phase, and the first connection of the reference capacitor, in particular at the same time as the sensor electrode is switched into the high-impedance state, is linked to the input of the AD converter and remains linked during the entire charge redistribution phase.

According to at least one embodiment, the at least one control unit is configured, during the charging phase and during the charge redistribution phase, to either connect the matching capacitor to the parallel circuit with the reference capacitor or to remove it from the parallel circuit by controlling the third switching element on the basis of a predefined measurement mode.

First, it is assumed that the matching capacitor is connected in parallel with the reference capacitor according to a first measurement mode, in particular during the charging phase and the charge redistribution phase. During the charge redistribution phase, the charge stored on the sensor electrode and/or the parallel circuit comprising the reference capacitor and the matching capacitor is redistributed in accordance with the respective capacitances of the reference capacitor, of the matching capacitor or of the effective capacitor of the sensor electrode with respect to ground via the resistance component. A voltage is then dropped across the parallel circuit, which depends both on whether the sensor electrode is touched or approached, and on the sum of the capacitances of the reference capacitor and of the matching capacitor. This voltage can then be measured by means of the AD converter, in particular in a readout phase following the charge redistribution phase, by means of the analog-to-digital converter.

On the other hand, if the matching capacitor is removed from the parallel circuit with the reference capacitor according to a second measurement mode, in particular during the charging phase and the charge redistribution phase, the charge stored on the sensor electrode and/or the reference capacitor is redistributed during the charge redistribution phase in accordance with the respective capacitances of the reference capacitor or of the effective capacitor of the sensor electrode with respect to ground via the resistance component. A voltage is then dropped across the parallel circuit, which depends both on whether the sensor electrode is touched or approached, and on the capacitance of the reference capacitor, but is independent of the capacitance of the matching capacitor. This voltage can then be measured by means of the AD converter, in particular in the readout phase, by means of the analog-to-digital converter.

According to at least one embodiment, the second connection of the reference capacitor is linked to the at least one first potential connection. A first connection of the matching capacitor can either be linked to the at least one first potential connection or can be switched into a high-impedance state by means of the third switching element. A second connection of the matching capacitor is linked to the first connection of the reference capacitor.

The matching capacitor can thus be connected in parallel with the reference capacitor by linking its first connection to the at least one first potential connection and can be removed from the parallel circuit by switching its first connection into the high-impedance state.

This is the case, for example, in the first interconnection example outlined above. In particular, in such embodiments, the first reference potential corresponds to the ground potential, in particular 0 V, and the second reference potential is different from zero, for example positive, for example 5 V with respect to ground.

According to at least one embodiment, the second connection of the reference capacitor is linked to the at least one second potential connection. The first connection of the matching capacitor can either be linked to the at least one second potential connection or can be switched into a high-impedance state by means of the third switching element of the sensor device. The second connection of the matching capacitor is linked to the first connection of the reference capacitor.

The matching capacitor can thus be connected in parallel with the reference capacitor by linking its first connection to the at least one second potential connection and can be removed from the parallel circuit by switching its first connection into the high-impedance state.

This is the case, for example, in the second interconnection example outlined above. In particular, in such embodiments, the second reference potential corresponds to the ground potential, in particular 0 V, and the first reference potential is different from zero, for example positive, for example 5 V with respect to ground.

In such embodiments, touching of or approach to the sensor electrode both during the charge redistribution phase and during the charging phase influences the voltage established across the reference capacitor in the charge redistribution phase.

According to at least one embodiment, the capacitance of the reference capacitor is greater than a capacitance of the matching capacitor, in particular at least twice the capacitance of the matching capacitor, for example at least three times the capacitance of the matching capacitor.

For example, the capacitance of the reference capacitor is in the range [2*C_{A}, 8*C_{A}], where C_{A} denotes the capacitance of the matching capacitor.

According to at least one embodiment, the sensor electrode has a first connection which is linked to the first switching element.

For example, the sensor electrode has no further connection. The resistance component is then arranged in particular between the first connection of the sensor electrode and the first connection of the reference capacitor.

According to at least one embodiment, the sensor electrode has the first connection which can either be linked to the at least one first potential connection or can be switched into the high-impedance state by means of the first switching element. The sensor electrode has a second connection which is linked to the first connection of the reference capacitor via the resistance component.

Such embodiments allow a functional check of the sensor electrode. For this purpose, a defined potential curve can be applied to one of the two connections of the sensor electrode, for example in a test phase, and a potential curve resulting at the other of the two connections of the sensor electrode can be measured, for example using the AD converter. For example, damage to the sensor electrode can be identified.

According to at least one embodiment, the sensor device has a further sensor electrode which is designed and arranged to be touched by the user and which can either be linked to the at least one first potential connection or switched into a high-impedance state by means of a further first switching element of the sensor device. The sensor device has a further resistance component which is used to link the further sensor electrode to the first connection of the reference capacitor.

The explanations regarding the sensor electrode, the first switching element and the resistance component can be transferred analogously to the further sensor electrode, the further first switching element and the further resistance component. Accordingly, in such embodiments, the touching or approach can be carried out both for the sensor electrode and for the further sensor electrode with only one AD converter. No further reference capacitor and/or matching capacitor is required either.

Depending on the design of the capacitances and resistances, it may be possible to check both the touching of or approach to the sensor electrode and the touching of or approach to the further sensor electrode with just one measurement. Alternatively, the sensor electrode and the further sensor electrode can be checked alternately.

According to at least one embodiment, the sensor device has a microcontroller containing the analog-to-digital converter, the first switching element and the second switching element. The sensor electrode and the reference capacitor are arranged outside the microcontroller, that is to say they are not part of the microcontroller. The sensor electrode is linked to a first contact of the microcontroller, wherein the first contact is linked to the first switching element. The first connection of the reference capacitor is linked to a second contact of the microcontroller, wherein the second contact is linked to the second switching element.

The first and/or the second contact, which can also be referred to as respective contact pins, can be, for example, GPIO pins (general purpose input/output pins) of the microcontroller. In particular, the first and the second contact may be on the same port of the microcontroller.

Microcontrollers are often, and preferably in the present case, configured in such a way that contacts of the microcontroller, in particular GPIO pins, can be switched into one or second different output states, wherein a first output state corresponds in the present case to a link to the first electrical reference potential and a second output state corresponds to a link to the second electrical reference potential. In other words, in the first output state, the first electrical reference potential can therefore be output at the corresponding contact, or, in the second output state, the second electrical reference potential can be output. In addition, contacts of the microcontroller, in particular GPIO pins, can be switched into an input state that corresponds to a high-impedance state. For this purpose, the corresponding contact can be opened, for example, or linked to a component with a high electrical resistance, for example the input of the AD converter.

For example, the first contact can be switched into the first output state during the charging phase in order to link the sensor electrode to the first electrical reference potential. For example, the second contact can be switched into the second output state during the charging phase in order to link the first connection of the reference capacitor to the second electrical reference potential. For example, the first contact can be switched into the input state during the charge redistribution phase in order to switch the sensor electrode into the high-impedance state. For example, the second contact can be switched into the input state during the charge redistribution phase in order to link the first connection of the reference capacitor to the input of an AD converter.

According to at least one embodiment, the microcontroller comprises the third switching element and the at least one control unit.

In alternative embodiments, the at least one control unit comprises the control unit for controlling the first and the second switching element and the further control unit for controlling the third switching element. The control unit is part of the microcontroller and the further control unit and the third switching element are arranged outside the microcontroller.

This may be advantageous, for example, with regard to the functional safety of the entire sensor device.

According to at least one embodiment, the matching capacitor is arranged outside the microcontroller and the microcontroller contains the third switching element. The matching capacitor, in particular the first connection of the matching capacitor, is linked to a third contact, in particular a GPIO pin, of the microcontroller, wherein the third contact is linked to the third switching element.

In alternative embodiments, the microcontroller comprises the matching capacitor and the third switching element. For example, the matching capacitor may correspond to a sample-and-hold capacitor of the AD converter or of a further AD converter of the microcontroller. This makes it possible to dispense with an additional component as a matching capacitor.

According to a further aspect of the invention, an input device for a motor vehicle for capturing a user input is specified. The input device has a sensor device according to the invention.

In particular, the input device may have a processing unit which, depending on the voltage determined in the readout phase by means of the AD converter, can detect the user input as touching of the sensor electrode or approach to the sensor electrode.

According to a further aspect of the invention, a hand detection device for a motor vehicle steering wheel is specified. The hand detection device has a sensor device according to the invention.

The sensor electrode can be arranged in particular on the motor vehicle steering wheel, with the result that it can be concluded from the touching of the sensor electrode that the user has a hand on the motor vehicle steering wheel.

Furthermore, according to further aspects of the invention, a motor vehicle steering wheel with a hand detection device according to the invention and a motor vehicle with an input device according to the invention and/or a motor vehicle steering wheel according to the invention are specified.

According to a further aspect of the invention, a method for capacitive touch detection, in particular by means of a sensor device according to the invention, is specified. A sensor electrode designed to be touched by a user is linked to a first electrical reference potential during a charging phase. A first connection of a reference capacitor, wherein the first connection is linked to the sensor electrode via a resistance component, is linked to a second electrical reference potential during the charging phase. The sensor electrode is switched into a high-impedance state during a charge redistribution phase following the charging phase and the first connection of the reference capacitor is linked to an input of an AD converter during the charge redistribution phase. In a readout phase following the charge redistribution phase, a voltage of the reference capacitor, i.e. a voltage applied between the first and a second connection of the reference capacitor, is measured by means of the AD converter. A matching capacitor is either connected to a parallel circuit with the reference capacitor or removed from the parallel circuit during the charging phase and during the charge redistribution phase on the basis of a predefined measurement mode.

According to at least one embodiment, touching of the sensor electrode by the user or an approach of a body part, in particular a finger or a hand, of the user to the sensor electrode is detected on the basis of the measured voltage, in particular by means of a processing unit.

For application cases or application situations which can result in the method and which are not explicitly described here, provision can be made, according to the method, for an error message and/or a request to input user feedback to be output and/or for a default setting and/or a predetermined initial state to be set.

Further embodiments of the method according to the invention follow directly from the various configurations of the sensor device according to the invention, the input device according to the invention and the hand detection device according to the invention, and vice versa. In particular, individual features and corresponding explanations and advantages regarding the various embodiments of the sensor device according to the invention, the input device according to the invention and the hand detection device according to the invention can be transferred in an analogous manner to corresponding embodiments of the method according to the invention. In particular, the sensor device according to the invention is designed or programmed to carry out a method according to the invention. In particular, the sensor device according to the invention carries out the method according to the invention.

Further features of the invention emerge from the claims, the figures, and the description of the figures. The features and combinations of features mentioned above in the description and the features and combinations of features mentioned below in the description of the figures and/or shown in the figures can be included in the invention not only in the combination specified in each case, but also in other combinations. In particular, embodiments and combinations of features that do not have all the features of an originally worded claim can also be included in the invention. Furthermore, embodiments and combinations of features that go beyond or differ from the combinations of features set out in the back-references of the claims can be included in the invention.

The invention is explained in more detail below on the basis of specific exemplary embodiments and associated schematic drawings. In the figures, identical or functionally identical elements may be provided with the same reference signs. The description of identical or functionally identical elements may not necessarily be repeated with respect to different figures.

In the figures:

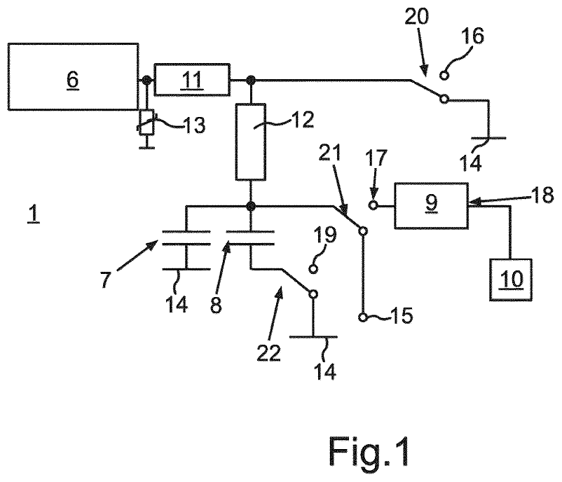

FIG. 1 shows a schematic block diagram of an exemplary embodiment of a sensor device according to the invention;

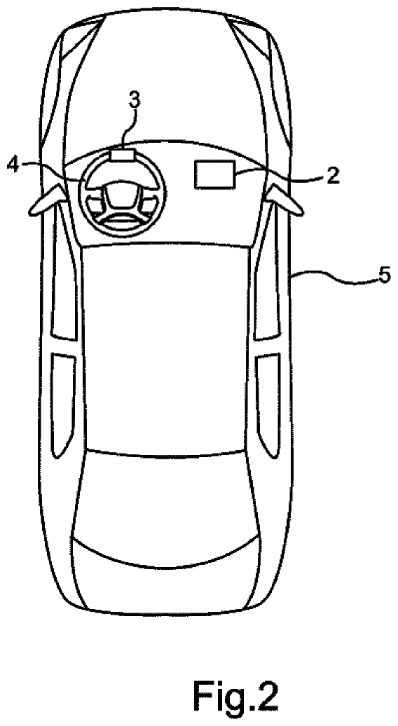

FIG. 2 shows a schematic illustration of a motor vehicle according to the invention;

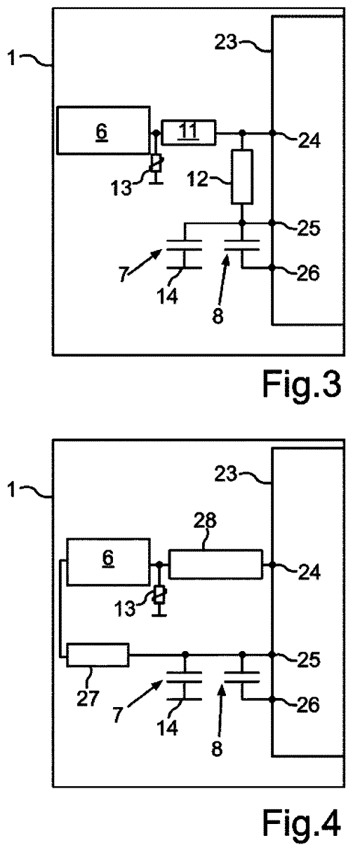

FIG. 3 shows a schematic block diagram of a further exemplary embodiment of a sensor device according to the invention;

FIG. 4 shows a schematic block diagram of a further exemplary embodiment of a sensor device according to the invention;

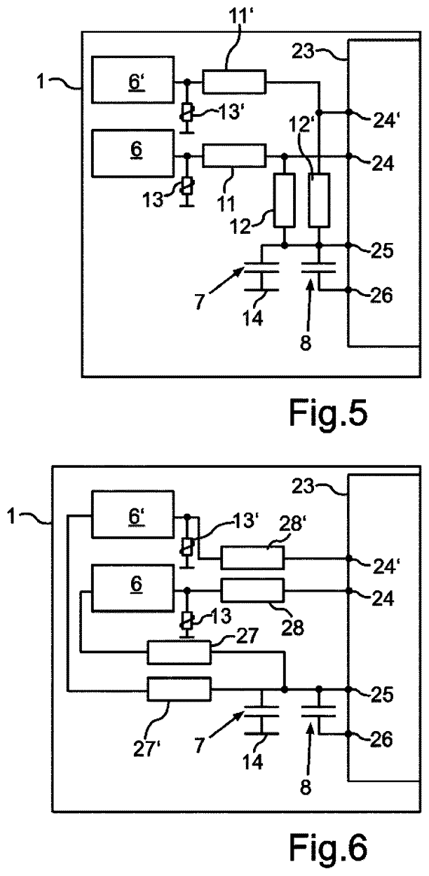

FIG. 5 shows a schematic block diagram of a further exemplary embodiment of a sensor device according to the invention;

FIG. 6 shows a schematic block diagram of a further exemplary embodiment of a sensor device according to the invention; and

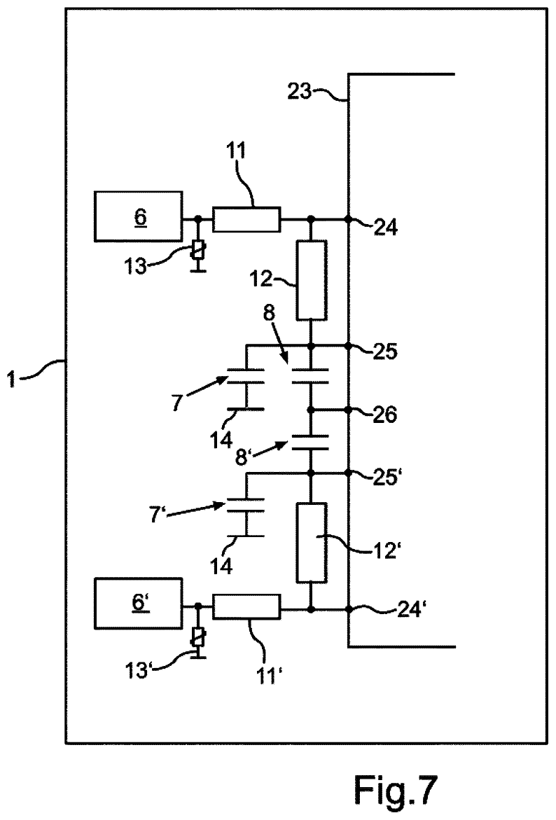

FIG. 7 shows a schematic block diagram of a further exemplary embodiment of a sensor device according to the invention.

FIG. 1 shows a schematic block diagram of an exemplary embodiment of a sensor device 1 according to the invention for capacitive touch detection. The sensor device 1 has an AD converter 9 and a sensor electrode 6 which is designed to be touched by a user. The sensor device 1 has at least one first potential connection 14 which is respectively connected to a first electrical reference potential, for example a ground potential, which by definition corresponds to a voltage of 0 V, for example. The sensor device 1 has at least one second potential connection 15 which is respectively connected to a second electrical reference potential, for example a potential which is different from the ground potential and by definition corresponds to a positive supply voltage U, for example. Depending on the design of the sensor device 1, the supply voltage can be, for example, 5 V with respect to the ground potential.

For example, an input 17 of the AD converter 9 corresponds to a high-impedance connection. The sensor device 1 may have one or more further high-impedance connections 16, 19 which can be, for example, floating connections, with the result that a respective link thus corresponds to an open circuit. Alternatively, the high-impedance connections 16, 19 can be linked to high electrical resistances (not shown), with the result that effectively no relevant current flow can occur via the high-impedance connections 16, 19. Alternatively, the high-impedance connections 16, 19 can be linked to the input 17 of the AD converter 9.

The sensor electrode 6 can either be linked to one of the first potential connections 14 or to the high-impedance connection 16 by means of a first switching element 20 of the sensor device 1. The sensor device 1 also has a reference capacitor 7 having a first connection, which can either be linked to one of the second potential connections 15 or to the input 17 of the analog-to-digital converter 9 by means of a second switching element 21 of the sensor device 1. A second connection of the reference capacitor is linked to one of the first potential connections 14. A resistance component 12 is arranged between the sensor electrode 6 and the first connection of the reference capacitor 7, with the result that the first switching element 20 is connected between the sensor electrode 6 and the resistance component 12. For example, a further resistance component 11 is arranged between the sensor electrode 6 and the resistance component 12, with the result that the first switching element 20 is connected between the resistance component 11 and the resistance component 12. A varistor 13 can be optionally provided between the sensor electrode 6 and ground in order to implement ESD protection.

The capacitance of an effective capacitor formed by the sensor electrode 6 with respect to ground depends on whether or not a user touches the sensor electrode 6, or how close a body part, such as a finger or a hand, of the user is to the sensor electrode 6. The capacitance can also be affected by ambient conditions such as the humidity or ambient temperature.

The sensor device 1 also has a matching capacitor 8 which can be either connected to a parallel circuit with the reference capacitor 7 or removed from the parallel circuit by means of a third switching element 22 of the sensor device 1. For this purpose, a first connection of the matching capacitor 8 can either be linked to one of the first potential connections 14 and to the high-impedance connection 19, for example by means of the third switching element 22. As already mentioned, the high-impedance connection 19 can be linked to or correspond to the input 17 of the AD converter 9. A second connection of the matching capacitor 8 is linked to the first input of the reference capacitor 7, that is to say, in each case like the first input of the reference capacitor 7, is linked either to one of the second potential connections 15 or to the input 17 of the AD converter 9 by means of the second switching element 21. Accordingly, the matching capacitor 8 is connected in parallel with the reference capacitor 7 when the first connection of the matching capacitor 8 is linked to the corresponding first potential connection 14, and is removed from the parallel circuit when the connection of the matching capacitor 8 is linked to the high-impedance connection 19.

The switching elements 20, 21, 22 can be, for example, in the form of transistors, in particular field effect transistors, which can be controlled, that is to say switched, by means of at least one control unit (not shown) of the sensor device 1.

A method according to the invention for capacitive touch detection can be carried out with the sensor device 1. For this purpose, the matching capacitor 8 is either permanently connected in parallel with the reference capacitor 7 according to a predefined measurement mode during a charging phase and a subsequent charge redistribution phase, or remains permanently removed from the parallel circuit during the charging phase and the charge redistribution phase, as explained above.

During the charging phase, the sensor electrode 6 is linked, for example, to the first potential connection 14 and the first connection of the reference capacitor 7 is linked to the second potential connection. Therefore, a voltage of 0 V is established across the effective capacitor formed by the sensor electrode 6 with respect to ground and the supply voltage U is established across the reference capacitor 7. If the matching capacitor 8 is connected in parallel with the reference capacitor 7, the supply voltage U is also established across the latter. The duration of the charging phase can be adapted accordingly in particular to the existing capacitances and resistances.

After the charging phase, the charge redistribution phase is initiated by switching the first and the second switching element 20, 21, in particular simultaneously, in order to link the sensor electrode 6 to the high-impedance connection 16 and to link the first connection of the reference capacitor 7 to the input 17 of the AD converter 9. As already mentioned, the third switching element 22 is not switched in this case, and so the matching capacitor 8 therefore remains connected in parallel with the reference capacitor 7 or remains removed from the parallel circuit according to the measurement mode.

Therefore, during the charge redistribution phase, charge flows from the reference capacitor 7 and, if the matching capacitor 8 is connected in parallel with the reference capacitor 7, to the sensor electrode 6. Accordingly, a voltage is established across the reference capacitor 7, which voltage depends on the ratio of the capacitance of the effective capacitor of the sensor electrode 6 to the sum of the capacitances of the reference capacitor 7 and of the matching capacitor 8, if the matching capacitor 8 is connected in parallel with the reference capacitor 7, and otherwise depends on the ratio of the capacitance of the effective capacitor of the sensor electrode 6 to the capacitance of the reference capacitor 7. This voltage is therefore also present at the input 17 of the AD converter. The duration of the charge redistribution phase can be adapted in particular to the existing capacitances and resistances, such that the charge redistribution is completed or substantially completed at the end of the charge redistribution phase.

In a readout phase following the charge redistribution phase, the voltage at the input 17 of the AD converter 9 can then be measured by means of the AD converter. The sensor device 1 may have, for example, an evaluation unit 10 which is linked to an output 18 of the AD converter and is configured to detect the touching of the sensor electrode 6 or the approach of the body part to the sensor electrode 6 by the user based on the measured voltage. For example, the measured voltage can be compared with one or more predefined threshold values. For example, if the user touches the sensor electrode 6, in particular during the charge redistribution phase, the capacitance of the effective capacitor of the sensor electrode 6 with respect to ground is greater than if the user does not touch it, since the touch acts as a further parallel capacitance.

In addition, the measured voltage, as mentioned, also depends on whether or not the matching capacitor 8 was connected in parallel with the reference capacitor 7 during the charging phase and the charge redistribution phase, i.e. the measurement mode. This can be advantageously used in various ways. For example, by selecting the measurement mode, the measurement range in which reliable touch detection can be achieved can be adapted to the size of the sensor electrode 6 and/or to material properties of the sensor electrode 6 and/or to a geometric design of the sensor electrode 6, such that the sensor device 1 can be flexibly used for different sensor electrodes 6 and applications. Furthermore, by selecting the measurement mode, the influence of the ambient conditions, in particular the ambient temperature, on the capacitance of the effective capacitor of the sensor electrode 6 can be at least partially compensated for, since capacitances of the reference capacitor 7 and of the matching capacitor 8 are regularly subject much less to the influence of the ambient conditions than the capacitance of the effective capacitor of the sensor electrode 6.

A plausibility check of the measured voltage can also be implemented by using the two different measurement modes in a targeted manner. When the state of the sensor electrode 6 remains unchanged with regard to the touching or approach by the user or other electrically conductive objects and under unchanged ambient conditions, the capacitance of the effective capacitor of the sensor electrode 6 is also unchanged. The measured voltages to be expected in the respective measurement modes, or their ratio to each other, can therefore be calculated or estimated within the scope of the measurement accuracy. In the event of a significant deviation, for example, a fault or defect in the sensor device can be concluded.

FIG. 2 schematically illustrates a motor vehicle 5 having an exemplary embodiment of a sensor device 1 according to the invention, as described in particular with regard to FIG. 1. The sensor device 1 can be, for example, part of an input device 2 according to the invention for capturing a user input. The sensor device 1 may also be part of a hand detection device 3 according to the invention for a motor vehicle steering wheel 4. In this case, the sensor electrode 6 is attached in particular to the motor vehicle steering wheel 4 of the motor vehicle 5.

FIG. 3 to FIG. 7 illustrate further exemplary embodiments of the sensor device 1 according to the invention for capacitive touch detection, which are based on the embodiment according to FIG. 1. For the sake of clarity, various components of the sensor device 1, for example the switching elements 20, 21, 22, the AD converter 9 and the evaluation unit 10, are not illustrated in FIG. 3 to FIG. 7. In the embodiments in FIG. 3 to FIG. 7, the sensor device 1 has a microcontroller 23 containing the AD converter 9, the first switching element 20 and the second switching element 21. The evaluation unit 10 may also be part of the microcontroller 23 or be provided separately therefrom. The microcontroller 23 also includes a control unit for controlling the first switching element 20 and the second switching element 21.

The microcontroller 23 has a first contact 24 which is designed in particular as a GPIO pin and is linked to the first switching element 20. The sensor electrode 6 is correspondingly linked to the first contact 24. The microcontroller 23 has a second contact 25 which is switchable or designed in particular as a GPIO pin and/or an analog-to-digital converter and is linked to the second switching element 21. The first connection of the reference capacitor 7 and the second connection of the matching capacitor 8 are linked accordingly to the second contact 24.

The microcontroller 23 may also include the third switching element 22 and a third contact 26, which is designed in particular as a GPIO pin and is linked to the third switching element 22. The first connection of the matching capacitor 8 is linked accordingly to the third contact 26. In this case, the control unit can also control the third switching element 22. In alternative embodiments, the matching capacitor 8 may also be integrated in the microcontroller 23. Even then, the control unit can control the third switching element 22.

In again alternative embodiments, both the third switching element 22 and the matching capacitor 8 can be provided outside the microcontroller 23. In this case, the sensor device 1 has, for example, a further control unit provided outside the microcontroller 23 in order to control the third switching element 22. This can be advantageous in terms of functional safety.

In a design example, the nominal resistances of the resistance components 11, 12 can each be 4.7 kΩ, for example, the nominal capacitance of the reference capacitor 7 can be 10 pF, for example, and the nominal capacitance of the matching capacitor 8 can be 2 pF, for example.

In the embodiment in FIG. 3, the sensor electrode 6 has only one first connection, for example. This configuration can therefore also be referred to as single-ended. In the embodiment in FIG. 4, the sensor electrode, on the other hand, has the first and a second connection. This configuration can therefore also be referred to as double-ended. In the embodiment in FIG. 4, the resistance components 11, 12 are replaced, for example, by a resistance component 28 between the first connection of the sensor electrode and the first contact 24 or the first switching element 20, and by a resistance component 27 between the second connection of the sensor electrode 6 and the first connection of the reference capacitor 7.

In a design example, the nominal resistance of the resistance component 27 can be 10 kΩ, for example, the nominal resistance of the resistance component 28 can be 1 kΩ, for example, the nominal capacitance of the reference capacitor 7 can be 10 pF, for example, and the nominal capacitance of the matching capacitor 8 can be 2 pF, for example.

The embodiment in FIG. 5 is based on that in FIG. 3. The sensor device 1 here additionally has a further sensor electrode 6′ with a corresponding optional varistor 13′. The further sensor electrode 6′ is linked to a further first contact 24′, for example a GPIO pin, of the microcontroller 23. The further first contact 24′ is linked to a further first switching element (not shown) of the microcontroller 23, by means of which the further sensor electrode 6′ can either be linked to one of the first potential connections 14 and the high-impedance connection 16 or to a further high-impedance connection. Provision is made of further resistance components 11′, 12′ which, in a similar manner to the resistance components 11, 12 for the sensor electrode 6, link the further sensor electrode 6′ to the first connection of the reference capacitor 7 and to the second contact 25 of the microcontroller 23. As described for the sensor electrode 6, the touching of the further sensor electrode 6′ can thus be detected without the need for a further AD converter, a further reference capacitor or a further matching capacitor.

The embodiment in FIG. 6 is based on the embodiment in FIG. 4, wherein a further sensor electrode 6′ is also provided, as in the embodiment in FIG. 5. Both sensor electrodes 6, 6′ are designed and interconnected in the embodiment in FIG. 6 according to the double-ended variant. Accordingly, further resistance components 27′, 28′ are provided for the further sensor electrode in a similar manner to the resistance components 27, 28.

The embodiment in FIG. 7 is based on the embodiment in FIG. 3 with a further sensor electrode 6′. In this embodiment, however, a further reference capacitor 7′, a further matching capacitor 8′ and further resistance components 11′, 12′ are provided, as well as further contacts 24′, 25′ of the microcontroller 23, a further first switching element and a further second switching element (not shown). The explanations of FIG. 1 and FIG. 3 with respect to the reference capacitor 7, the matching capacitor 8, the resistance components 11, 12, the contacts 24, 25, the first and the second switching element can be transferred analogously to the further reference capacitor 7′, the further matching capacitor 8′, the resistance components 11′, 12′, the contacts 24′, 25′, the further first and the further second switching element.

However, the first connection of the further matching capacitor 8′, like the first connection of the matching capacitor 8, is linked to the third contact 26 of the microcontroller 23, which can thus be advantageously used twice.

As described in particular with reference to the figures, the invention allows the touch detection reliability to be improved when using a capacitive measurement principle for a larger measurement range and or for different measurement ranges.

In particular, the invention allows a flexible choice of the reference capacitance which can correspond to the capacitance of the reference capacitor or to the sum of the capacitances of the reference capacitor and of the matching capacitor, depending on the measurement mode. This can also be expanded by one or more further matching capacitors, each of which can be either added to or removed from the parallel circuit, depending on the measurement mode.

Since the measurement range for certain applications, for instance hand detection for a motor vehicle steering wheel, can be very small, for instance at low temperatures, low humidity and/or when the user's hands are not on the steering wheel, but also very large, for instance at high temperatures, high humidity and/or with maximum coverage of the steering wheel by the hands, a high resolution of the measurement can be achieved with the invention in each case by bringing the measured capacitance and the reference capacitance to the same or a similar level if possible.

The invention can increase the quality of the measured signal. Plausibility checks can also be performed in order to check the entire measurement chain. Although a change in the reference capacitance leads to different measured values, the measured values for measurements with and without a connected matching capacitor can be checked for plausibility or consistency using a transfer function or a look-up table, which increases the error detection for the entire measurement and evaluation chain.

1. A sensor device for capacitive touch detection, comprising:
at least one first potential connection for respectively connecting the sensor device to a first electrical reference potential and at least one second potential connection for respectively connecting the sensor device to a second electrical reference potential;
an analog-to-digital converter and a sensor electrode, each of which is designed to be touched by a user and which is either linked to the at least one first potential connection or switched into a high-impedance state by means of a first switching element of the sensor device;
a reference capacitor having a first connection, which is either linked to the at least one second potential connection or to an input of the analog-to-digital converter by means of a second switching element of the sensor device; and
a resistance component which is used to link the sensor electrode to the first connection of the reference capacitor;
wherein the sensor device has a matching capacitor which is either connected to a parallel circuit with the reference capacitor or removed from the parallel circuit by means of a third switching element of the sensor device.

2. The sensor device as claimed in claim 1,
wherein the sensor device has at least one control unit which is configured, during a charging phase, to link the sensor electrode to the at least one first potential connection by controlling the first switching element and to link the first connection of the reference capacitor to the at least one second potential connection by controlling the second switching element.

3. The sensor device as claimed in claim 2,
wherein the at least one control unit is configured, during a charge redistribution phase following the charging phase, to switch the sensor electrode into the high-impedance state by controlling the first switching element and to link the first connection of the reference capacitor to the input of the analog-to-digital converter by controlling the second switching element.

4. The sensor device as claimed in claim 3,
wherein the at least one control unit is configured, during the charging phase and during the charge redistribution phase, to either connect the matching capacitor to the parallel circuit with the reference capacitor or to remove it from the parallel circuit by controlling the third switching element on the basis of a predefined measurement mode.

5. The sensor device as claimed in claim 1,
wherein a second connection of the reference capacitor is linked to the at least one first potential connection and a first connection of the matching capacitor is either linked to the at least one first potential connection or switched into a high-impedance state by means of the third switching element of the sensor device, and a second connection of the matching capacitor is linked to the first connection of the reference capacitor; or
a second connection of the reference capacitor is linked to the at least one second potential connection and a first connection of the matching capacitor is either linked to the at least one second potential connection or switched into a high-impedance state by means of the third switching element of the sensor device, and a second connection of the matching capacitor is linked to the first connection of the reference capacitor.

6. The sensor device as claimed in claim 1,
wherein a capacitance of the reference capacitor is at least twice a capacitance of the matching capacitor.

7. The sensor device as claimed in claim 1,
wherein the sensor electrode has a first connection which is either linked to the at least one first potential connection or switched into the high-impedance state by means of the first switching element of the sensor device; and
wherein the sensor electrode has a second connection which is linked to the first connection of the reference capacitor via the resistance component.

8. The sensor device as claimed in claim 1,
wherein the sensor device has a further sensor electrode which is designed to be touched by the user and which is either linked to the at least one first potential connection or switched into a high-impedance state by means of a further first switching element of the sensor device; and
wherein a further resistance component is used to link the further sensor electrode to the first connection of the reference capacitor.

9. The sensor device as claimed in claim 1,
wherein the sensor device has a microcontroller containing the analog-to-digital converter, the first switching element and the second switching element, wherein the sensor electrode and the reference capacitor are arranged outside the microcontroller;
wherein the sensor electrode is linked to a first contact of the microcontroller, wherein the first contact is linked to the first switching element; and
wherein the first connection of the reference capacitor is linked to a second contact of the microcontroller, wherein the second contact is linked to the second switching element.

10. The sensor device as claimed in claim 9,
wherein one or more of the first contact and the second contact is designed as a general purpose input/output (GPIO) pin of the microcontroller.

11. The sensor device as claimed in claim 9,
wherein the matching capacitor is arranged outside the microcontroller and the microcontroller contains the third switching element; and
wherein the matching capacitor is linked to a third contact of the microcontroller, wherein the third contact is linked to the third switching element.

12. An input device for a motor vehicle for capturing a user input, the input device comprising: a sensor device as claimed in claim 1.

13. A hand detection device for a motor vehicle steering wheel, having a sensor device as claimed in claim 1.

14. A method for capacitive touch detection, comprising:
linking a sensor electrode designed to be touched by a user to a first electrical reference potential during a charging phase;
linking a first connection of a reference capacitor linked to the sensor electrode via a resistance component to a second electrical reference potential during the charging phase;
switching the sensor electrode into a high-impedance state during a charge redistribution phase following the charging phase;
linking the first connection of the reference capacitor to an input of an analog-to-digital converter during the charge redistribution phase; and
measuring a voltage of the reference capacitor by means of the analog-to-digital converter in a readout phase following the charge redistribution phase,
wherein a matching capacitor is either connected to a parallel circuit with the reference capacitor or removed from the parallel circuit during the charging phase and during the charge redistribution phase on the basis of a predefined measurement mode.

15. The method as claimed in claim 14, comprising:
linking a first connection of the matching capacitor to the first electrical reference potential or switching into a high-impedance state during the charging phase and during the charge redistribution phase on the basis of the predefined measurement mode, wherein a second connection of the reference capacitor is linked to the first electrical reference potential; or
linking a first connection of the matching capacitor to the second electrical reference potential or switching into a high-impedance state during the charging phase and during the charge redistribution phase on the basis of the predefined measurement mode, wherein a second connection of the reference capacitor is linked to the second electrical reference potential.
